(19) United States
(12) Patent Application Publication
(10) Pub. No.: US 2025/0026979 A1
(43) Pub. Date: Jan. 23, 2025

(54) QUANTUM DOT FILM, AND QUANTUM DOT LIGHT-EMITTING DIODE AND PREPARATION METHOD THEREFOR

(71) Applicant: TCL TECHNOLOGY GROUP CORPORATION, Huizhou, Guangdong (CN)

(72) Inventors: Zhiwen NIE, Huizhou, Guangdong (CN); Xiaolin YAN, Huizhou, Guangdong (CN)

(73) Assignee: TCL TECHNOLOGY GROUP CORPORATION, Huizhou, Guangdong (CN)

(21) Appl. No.: 18/708,605

(22) PCT Filed: Oct. 21, 2022
(86) PCT No.: PCT/CN2022/126607

§ 371 Date: May 9, 2024

(30) Foreign Application Priority Data
Nov. 9, 2021 (CN) 202111322270.0

(51) Int. Cl. C09K 11/56; H10K 50/115; H10K 50/15; H10K 50/16; H10K 50/81; H10K 50/82; H10K 71/13

(52) U.S. Cl. CPC C09K 11/565; H10K 50/115; H10K 50/15; H10K 50/16; H10K 50/81; H10K 50/82; H10K 71/13; C09K 2211/188

(57) ABSTRACT

Provided in the embodiments of the present application are a quantum dot film, and a quantum dot light-emitting diode and a preparation method therefor. The quantum dot film comprises a first quantum dot, a second quantum dot and a first ligand. By means of the first ligand, first excitons generated by the first quantum dot can be stacked with second excitons generated by the second quantum dot, and the quantum dots of the whole hybrid system have the advantages of quantum dots of two different types by means of the stacking effect between the excitons, such that the light emission performance of the quantum dot light-emitting diode is improved.

This disclosure claims priority of the Chinese patent disclosure with the Chinese Patent Disclosure No. 202111322270.0, filed in the China National Intellectual Property Administration on Nov. 9, 2021, and entitled “QUANTUM DOT FILM, QUANTUM DOT LIGHT-EMITTING DIODE AND PREPARATION METHOD THEREFOR, AND DISPLAY DEVICE”, which is incorporated herein by reference in its entirety.

### TECHNICAL FIELD

The present disclosure relates to the field of display technologies, and more particularly, to a quantum dot film, a quantum dot light-emitting diode and a preparation method therefor.

### BACKGROUND

Self-luminous Quantum Dot Light-Emitting Diode (QLED) devices using inorganic quantum dots as electroluminescent materials have advantages of wide color gamut coverage, high color purity, ultra-thin and light weight, and can be bent and curled. Therefore, it has received widespread attention from academic and industrial circles.

Nowadays, the external quantum efficiency and lifetime of red QLED and green QLED are comparable to those of organic electroluminescent devices. However, the device performance of blue QLED, especially the lifetime of the blue QLED, is still far behind. Therefore, how to further improve the lifetime of blue QLED is a key technical issue for QLED to truly realize commercialization at this stage. The prior technology selects different quantum dot film materials to prepare QLED devices with different external quantum efficiencies. Among them, QLED device prepared by one type of quantum dot film materials have high external quantum efficiency, however the measured lifetime of such QLED device is often very low; QLED device prepared by another type of quantum dot film materials have higher measured lifetime, however such QLED device has low external quantum efficiency. Therefore, it is difficult for QLED device prepared by the existing quantum dot film materials to have the characteristic of high measured lifetime while having the characteristic of high external quantum efficiency.

In summary, it is indeed necessary to develop a quantum dot film, a quantum dot light-emitting diode, a preparation method for the quantum dot light-emitting diode, and a display device to overcome the shortcomings of the existing technology.

### Technical Problems

It is difficult for QLED device made of existing quantum dot film materials to have the characteristic of high measured lifetime while having the characteristic of high external quantum efficiency.

### Technical Solutions

Therefore, the present disclosure provides a quantum dot film, a quantum dot light-emitting diode and a preparation method therefor.

Embodiments of the present disclosure provide a quantum dot film, the quantum dot film includes quantum dots, surfaces of at least part of the quantum dots connected with a first ligand, and the quantum dots include a first quantum dot and a second quantum do. The first ligand is configured to stack first excitons generated by the first quantum dot with second excitons generated by the second quantum dot.

Alternatively, in some embodiments of the present disclosure, an external quantum efficiency of a first quantum dot light-emitting diode prepared by the first quantum dot alone is greater than or equal to 10%, a measured lifetime of the first quantum dot light-emitting diode at a brightness of 1000 nit is less than or equal to 1 h, and a measured lifetime of a second quantum dot light-emitting diode prepared by the second quantum dot at the brightness of 1000 nit is between 1 h and 20 h.

Alternatively, in some embodiments of the present disclosure, the external quantum efficiency of the first quantum dot light-emitting diode prepared by the first quantum dot alone is between 10% and 22%.

Alternatively, in some embodiments of the present disclosure, the measured lifetime of the second quantum dot light-emitting diode prepared by the second quantum dot at the brightness of 1000 nit is between 3 h and 10 h.

Alternatively, in some embodiments of the present disclosure, the first ligand is selected from an exciton delocalized ligand.

Alternatively, in some embodiments of the present disclosure, the exciton delocalized ligand is selected from one or more of phenyl dithiocarbamate and 1, 3-dimethyl-4, 5-disubstituted imidazole subunit N-heterocyclic carbene.

Alternatively, in some embodiments of the present disclosure, a mass percentage of the first ligand in the quantum dot film ranges from 2% to 15%.

Alternatively, in some embodiments of the present disclosure, the mass percentage of the first ligand in the quantum dot film ranges from 2% to 8%.

Alternatively, in some embodiments of the present disclosure, a mass ratio of the first quantum dot to the second quantum dot ranges from 1:1 to 1:10.

Alternatively, in some embodiments of the present disclosure, a luminescence wavelength of the first quantum dot and a luminescence wavelength of the second quantum dot are in a same wavelength band, and an energy band width of the first quantum dot and an energy band width of the second quantum dot are the same. The energy band width refers to an energy range between a lowest energy level and a highest energy level in an energy band.

Alternatively, in some embodiments of the present disclosure, the first quantum dot and the second quantum dot are independently selected from a core-shell structure quantum dot.

Alternatively, in some embodiments of the present disclosure, the first quantum dot and the second quantum dot are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAINAs, GaAINSb, GaAlPAs, GaAlPSb, GaInNP, GaInNAs, GaInNSb, GalnPAs, GaInPSb, InAINP, InAINAs, InAINSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and a material of the first quantum dot and a material of the second quantum dot are different.

Correspondingly, the embodiments of the present disclosure further provide a quantum dot light-emitting diode, the quantum dot light-emitting diode includes a first electrode, a second electrode, and a quantum dot light-emitting layer disposed between the first electrode and the second electrode. The quantum dot light-emitting layer is prepared by the quantum dot film above.

Alternatively, in some embodiments of the present disclosure, one of the first electrode and the second electrode is an anode, and another is a cathode; the quantum dot light-emitting diode includes a hole injection layer, a hole transport layer, and an electron transport layer. The hole injection layer and the hole transport layer are disposed between the anode and the quantum dot light-emitting layer, the hole injection layer is disposed close to the anode side, the hole transport layer is disposed close to the quantum dot light-emitting layer, and the electron transport layer is disposed between the cathode and the quantum dot light-emitting layer. A material of the hole injection layer includes any one of poly (ethylene dioxythiophene):polystyrene sulfonate, poly (9,9-dioctyl-fluorene-co-N-(4-butylphenyl)-diphenylamine), polyarylamine, poly(N-vinylcarbazole), polyaniline, polypyrrole, N,N′,N′-tetrakis (4-methoxyphenyl)-benzidine, 4-bis [N-(1-naphthyl)-N-phenyl-amino]biphenyl, 4,4′,4″-tri[phenyl(m-tolyphenyl) amino] triphenylamine, 4,4′,4″-tri (N-carbazolyl) aniline, triphenylamine, 4,4′-cyclohexylbis [N,N-bis(4-methylphenyl)] doped with 4,4′4″-Tris(N,N-diphenylamino)triphenylamine tetrafluoro-tetracyanoquinone dimethane, p-doped phthalocyanines, F4-TCNQ-doped N,N-diphenyl-N,N-bis(1-naphthyl)-1,1-biphenyl-4,4″-diamine, and hexaaza-benzphenanthrene-hexanthrene. A material of the hole transport layer includes one or more of an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, Poly (ethylene dioxythiophene):polystyrene sulfonate and derivatives thereof, poly(N-vinyl carbazole) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine, and spiro-NPB. A material of the electron transport layer includes a first inorganic material or an a first organic material. The first inorganic material includes one or more of an undoped metal/non-metal oxide, a doped metal/non-metal oxide, an undoped semiconductor particle, a doped semiconductor particle, and a nitride. The doped metal/non-metal oxide is doped with Al, Mg, In, Li, Ga, Cd, Cs or Cu, and the doped semiconductor particle is doped with Al, Mg, In, Li, Ga, Cd, Cs or Cu. The first organic material includes one or more of an oxazole compound, an isoxazole compound, a triazole compound, an isothiazole compound, an oxadiazole compound, a thiadiazole compound, a perylene compound, and an aluminum complex. A material of the anode includes one or more of ITO, IZO, ITZO, ICO, SnO₂, In₂O₃, Cd:ZnO, F:SnO₂, In:SnO₂, Ga:SnO₂, AZO, Ni, Pt, Au, Ag, Ir, and CNT; a material of the cathode includes one or more of Ca, Ba, Ca/Al, LiF/Ca, LiF/Al, BaF₂/Al, CsF/Al, CaCO₃/Al, BaF₂/Ca/Al, Al, Mg, Au:Mg, and Ag:Mg.

Correspondingly, the embodiments of the present disclosure further provide a preparation method for a quantum dot light-emitting diode including: providing a first electrode; forming a quantum dot film on the first electrode, and thermally annealing to form a quantum dot light-emitting layer; and forming a second electrode on the quantum dot light-emitting layer. The quantum dot film includes quantum dots, surfaces of at least part of the quantum dots are connected with a first ligand, the quantum dots include a first quantum dot and a second quantum dot. The first ligand is configured to stack first excitons generated by the first quantum dot with second excitons generated by the second quantum dot.

Alternatively, in some embodiments of the present disclosure, forming a quantum dot film on the first electrode includes: disposing a quantum dot ink on the first electrode to form a wet film, placement treating, and drying to form the quantum dot film.

Alternatively, in some embodiments of the present disclosure, a pressure of the placement treating is a normal pressure, and a time of the placement treating is from 2 min to 10 min.

Alternatively, in some embodiments of the present disclosure, a temperature of the placement treating is from 10° C. to 35° C.

Alternatively, in some embodiments of the present disclosure, a temperature of the thermally annealing is between 50° C. and 120° C., and a time of the thermally annealing is between 5 min and 30 min.

Alternatively, in some embodiments of the present disclosure, one of the first electrode and the second electrode is an anode, and another is a cathode. The method includes: forming a hole injection layer and a hole transport layer between the anode and the quantum dot light-emitting layer, wherein, the hole injection layer is disposed close to the anode side, and the hole transport layer is disposed close to the quantum dot light-emitting layer; and forming an electron transport layer between the cathode and the quantum dot light-emitting layer. A material of the hole injection layer includes any one of poly (ethylene dioxythiophene):polystyrene sulfonate, poly (9,9-dioctyl-fluorene-co-N-(4-butylphenyl)-diphenylamine), polyarylamine, poly(N-vinylcarbazole), polyaniline, polypyrrole, N,N′,N′-tetrakis (4-methoxyphenyl)-benzidine, 4-bis [N-(1-naphthyl)-N-phenyl-amino]biphenyl, 4,4′,4″-tri[phenyl(m-tolyphenyl) amino] triphenylamine, 4,4′,4″-tri (N-carbazolyl) triphenylamine, 4,4′-cyclohexylbis [N,N-bis(4-methylphenyl)] aniline, 4,4′4″-Tris(N,N-diphenylamino)triphenylamine doped with tetrafluoro-tetracyanoquinone dimethane, p-doped phthalocyanines, F4-TCNQ-doped N,N-diphenyl-N,N-bis(1-naphthyl)-1,1-biphenyl-4,4″-diamine, and hexaaza-benzphenanthrene-hexanthrene. A material of the hole transport layer includes one or more of an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, Poly (ethylene dioxythiophene):polystyrene sulfonate and derivatives thereof, poly(N-vinyl carbazole) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine, and spiro-NPB. A material of the electron transport layer includes a first inorganic material or an a first organic material. The first inorganic material includes one or more of an undoped metal/non-metal oxide, a doped metal/non-metal oxide, an undoped semiconductor particle, a doped semiconductor particle, and a nitride. The doped metal/non-metal oxide is doped with Al, Mg, In, Li, Ga, Cd, Cs or Cu, and the doped semiconductor particle is doped with Al, Mg, In, Li, Ga, Cd, Cs or Cu. The first organic material includes one or more of an oxazole compound, an isoxazole compound, a triazole compound, an isothiazole compound, an oxadiazole compound, a thiadiazole compound, a perylene compound, and an aluminum complex. A material of the anode includes one or more of ITO, IZO, ITZO, ICO, SnO₂, In₂O₃, Cd:ZnO, F:SnO₂, In:SnO₂, Ga:SnO₂, AZO, Ni, Pt, Au, Ag, Ir, and CNT. A material of the cathode includes one or more of Ca, Ba, Ca/Al, LiF/Ca, LiF/Al, BaF₂/Al, CsF/Al, CaCO₃/Al, BaF₂/Ca/Al, Al, Mg, Au:Mg, and Ag:Mg.

### Advantageous Effects

The quantum dot film of the present disclosure includes quantum dots, and surfaces of at least part of the quantum dots are connected with a first ligand. the quantum dots include a first quantum dot and a second quantum dot, wherein, the first ligand is configured to stack first excitons generated by the first quantum dot with second excitons generated by the second quantum dot. The above-mentioned quantum dot film adds the first ligand between the first quantum dot and the second quantum dot, the first ligand can stack the first excitons generated by the first quantum dot and the second excitons generated by the second quantum dot. A stacking effect between the first excitons and the second excitons cause a part of the first excitons to follow the second excitons stacked with themselves to radiative recombination output into a core shell of the second quantum dot, and at a same time cause a part of the second excitons to follow the first excitons stacked with themselves to radiative recombination output into a core shell of the first quantum dot, so that the first quantum dot and/or the second quantum dot possess both the first excitons and the second excitons, thereby making the quantum dots of the entire hybrid system possess advantages of two different types of quantum dots, thus to make the quantum dot light-emitting diode prepared by the above-mentioned quantum dot film possess characteristics of the first quantum dot light-emitting diode prepared by the first quantum dot alone and characteristics of the second quantum dot light-emitting diode prepared by the second quantum dot alone, thus further improving light emission performance of the quantum dot light-emitting diode.

### BRIEF DESCRIPTION OF FIGURES

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a cross-sectional view of a quantum dot light-emitting diode according to an embodiment of the present disclosure;

FIG. 2 is a flowchart of a preparation method for a quantum dot light-emitting diode according to an embodiment of the present disclosure.

FIG. 3 is a flowchart of a preparation method for a quantum dot light-emitting device according to another embodiment of the present disclosure.

### EMBODIMENTS OF THE PRESENT DISCLOSURE

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

It should be noted that the order in which the following embodiments are described is not intended to limit the preferred order of the embodiments. Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association relationship of associated objects, and means that there may be three relationships, for example, “A and/or B” may refer to three relationships: for example, A exists alone, A and B exist at the same time, and B exists alone, where A and B may be singular or plural.

In the present disclosure, the terms “at least one” refer to one or more, and “a plurality of/multiple” refers to two or more. The terms “at least one”, “at least one of the followings”, or the like, refer to any combination of the items listed, including any combination of a single item or a plurality of items. For example, “at least one of a, b, or c” or “at least one of a, b, and c” may refer to: a, b, c, a-b (i.e., a and b), a-c, b-c, or a-b-c, where a, b, and c may be single or plural (multiple).

Aiming at a technical problem that the QLED device prepared by an existing quantum dot film materials is difficult to have a characteristic of high measured lifetime while having the characteristic of high external quantum efficiency, embodiments of the present disclosure can improve the above technical problem.

Embodiments of the present disclosure provides a quantum dot film, the quantum dot film includes quantum dots, surfaces of at least part of the quantum dots are connected with a first ligand. The quantum dots include a first quantum dot and a second quantum dot. The first ligand is configured to stack first excitons generated by the first quantum dot with second excitons generated by the second quantum dot.

Specifically, embodiments of the present disclosure provide a quantum dot film including a first quantum dot, a second quantum dot, and a first ligand connected to the first quantum dot and/or the second quantum dot.

Moreover, the first ligand is configured to stack first excitons generated by the first quantum dot with second excitons generated by the second quantum dot.

It can be understood that, in the quantum dot film, it can be that, only a surface of the first quantum dot is connected with the first ligand, or only a surface of the second quantum dot is connected with the first ligand, or both the surface of the first quantum dot and the surface of the second quantum dot are connected with the first ligand. Preferably, both the surface of the first quantum dot and the surface of the second quantum dot are connected with the first ligand.

The quantum dot film provided by the embodiments of the present disclosure adds the first ligand between the first quantum dot and the second quantum dot, the first ligand can stack the first excitons generated by the first quantum dot and the second excitons generated by the second quantum dot. A stacking effect between the first excitons and the second excitons can make the quantum dots of the entire hybrid system possess advantages of two different types of quantum dots, thus to have the quantum dot light-emitting diode prepared by the above-mentioned quantum dot film possess characteristics of high efficiency and high measured lifetime. Therefore, the contradiction between the high efficiency and the high measured lifetime of a conventional quantum dot light-emitting diode is solved to a certain extent, and a performance of the quantum dot light-emitting diode is further improved.

Technical solutions of the present disclosure are described in conjunction with specific embodiments.

Firstly, embodiments of the present disclosure provide a quantum dot film including a first quantum dot, a second quantum dot, and a first ligand connected to the first quantum dot and/or the second quantum dot. The first ligand is configured to stack first excitons generated by the first quantum dot with second excitons generated by the second quantum dot.

In embodiments of the present disclosure, an external quantum efficiency of a first quantum dot light-emitting diode prepared by the first quantum dot alone is at least greater than or equal to 10%, preferably between 10% and 22%. A measured lifetime of the first quantum dot light-emitting diode at a brightness of 1000 nit is less than or equal to 1 h. A measured lifetime of a second quantum dot light-emitting diode prepared by the second quantum dot at the brightness of 1000 nit is between 1 h and 20 h, preferably between 3 h and 10 h.

Moreover, the external quantum efficiency is a ratio of the number of electron-hole logarithms injected into quantum dots to the number of emitted photons. The unit of the external quantum efficiency is %. The external quantum efficiency is an important parameter to measure the pros and cons of electroluminescent devices. The external quantum efficiency can be determined by external quantum optical testing instruments, the test conditions are carried out at room temperature, and the air humidity is 30%-60%.

Moreover, the lifetime is a time required when the brightness is reduced to a certain proportion of the maximum brightness under a constant current or a constant voltage drive. A time when the brightness is reduced to 95% of the maximum brightness is defined as T95, and this lifetime is the measured life. The test condition is using the lifetime test system to test the lifetime of a corresponding QLED device at room temperature, and the air humidity is 30-60%.

In the embodiments of the present disclosure, the first ligand includes at least one of phenyl dithiocarbamate (PDTC) and 1,3-dimethyl-4,5-disubstituted imidazole subunit N-heterocyclic carbene (NHC).

In the embodiments of the present disclosure, a mass percentage of the first ligand in the quantum dot film ranges from 2% to 15%.

In the embodiments of the present disclosure, the first quantum dot or the second quantum dot includes a combination formed of at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAlNSb, GaAlPAs, GaAlPSb, GaInNP, GaInNAs, GaInNSb, GalnPAs, GaInPSb, InAINP, InAINAs, InAINSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

In embodiments of the present disclosure, a mass ratio of the first quantum dot to the second quantum dot ranges from 1:1 to 1:10.

Accordingly, the embodiments of the present disclosure further provide a quantum dot light-emitting diode prepared by the quantum dot film. The quantum dot light-emitting diode includes a first electrode, a second electrode, and a quantum dot light-emitting layer disposed between the first electrode and the second electrode. Moreover, the quantum dot light-emitting layer is a quantum dot light-emitting layer prepared by the quantum dot film provided in the present disclosure.

The quantum dot light-emitting layer is formed by the quantum dot film provided by the present disclosure. The quantum dot light-emitting layer includes quantum dots, surfaces of at least part of the quantum dots are connected with a first ligand. The quantum dots include a first quantum dot and a second quantum dot, wherein, the first ligand is configured to stack first excitons generated by the first quantum dot with second excitons generated by the second quantum dot which surfaces of at least part of the quantum dots are connected with the first ligand.

Specifically, the quantum dot light-emitting layer includes the first quantum dot, the second quantum dot, and the first ligand connected to the first quantum dot and/or the second quantum dot.

Moreover, one of the first electrode and the second electrode is an anode, and another is a cathode.

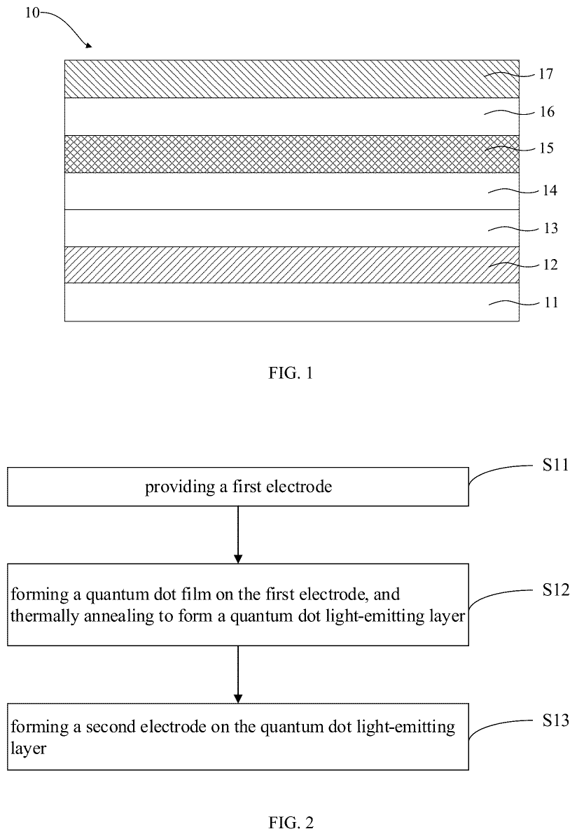

As shown in FIG. 1, a cross-sectional view of a quantum dot light-emitting diode according to an embodiment of the present disclosure. The quantum dot light-emitting diode 10 includes a substrate 11, an anode 12 disposed on the substrate 11, a hole injection layer 13 disposed on the anode 12, a hole transport layer 14 disposed on the hole injection layer 13, an electron transport layer 16 disposed on the hole transport layer 14, and a cathode 17 disposed on the electron transport layer 16.

Moreover, the quantum dot light-emitting layer 15 is disposed between the hole transport layer 14 and the electron transport layer 16. The quantum dot light-emitting layer 15 includes the first quantum dot, the second quantum dot, and the first ligand connected to the first quantum dot and/or the second quantum dot.

Moreover, an external quantum efficiency of a first quantum dot light-emitting diode prepared by the first quantum dot alone is greater than or equal to 10% and less than or equal to 22% (between 10% and 22%), and a measured lifetime of a second quantum dot light-emitting diode prepared by the second quantum dot at the brightness of 1000 nit is between 1 h and 20 h. The first ligand is configured to couple the first excitons generated by the first quantum dot with the second excitons generated by the second quantum dot.

Specifically, the substrate 11 includes a steel substrate or a flexible substrate, and in particular includes glass, silicon wafer, polycarbonate, polymethyl methacrylate, polyethylene terephthalate, polyethylene naphthalate, polyamide, polyethersulfone, or combinations thereof.

Specifically, the anode 12 is formed of a conductive material having a relatively high work function, which may be formed of a doped metal oxide or an undoped metal oxide, such as ITO, IZO, ITZO, ICO, SnO₂, In₂O₃, Cd:ZnO, F:SnO₂, In:SnO₂, Ga:SnO₂, AZO, and the like. In addition to the doped metal oxide and the undoped metal oxide, the anode 12 may be formed of a metal material including nickel (Ni), platinum (Pt), gold (Au), silver (Ag), iridium (Ir), or carbon nanotubes (CNT).

Specifically, a material of the hole injection layer 13 includes at least one of poly (ethylene dioxythiophene):polystyrene sulfonate (PEDOT:PSS), poly (9,9-dioctyl-fluorene-co-N-(4-butylphenyl)-diphenylamine) (TFB), polyarylamine, poly(N-vinylcarbazole), polyaniline, polypyrrole, N,N′,N′-tetrakis (4-methoxyphenyl)-benzidine (TPD), 4-bis [N-(1-naphthyl)-N-phenyl-amino] biphenyl (α-NPD), 4,4′,4″-tri[phenyl(m-tolyphenyl) amino] triphenylamine (m-MTDATA), 4,4′,4″-tri (N-carbazolyl) triphenylamine (TCTA), (TAPC), 4,4′-cyclohexylbis [N,N-bis(4-methylphenyl)] aniline 4,4′4″-Tris(N,N-diphenylamino)triphenylamine (TDATA) doped with tetrafluoro-tetracyanoquinone dimethane (F4-TCNQ), p-doped phthalocyanines (e.g., F4-TCNQ-doped zinc phthalocyanine (ZnPc)), F4-TCNQ-doped N,N-diphenyl-N,N-bis(1-naphthyl)-1,1-biphenyl-4,4″-diamine (α-NPD), and hexaaza-benzphenanthrene-hexanthrene (HAT-CN).

Specifically, when the hole transport layer 14 includes an organic material, the organic material includes an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, PEDOT:PSS and derivatives thereof, poly(N-vinyl carbazole) (PVK) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine (NPB), spiro-NPB, or combinations thereof. The aryl amine includes 4,4′-N,N′-diphenyl-N,N′-bis (1-naphthyl)-1,1′-biphenyl-4,4″-diamine (α-NPD), N, N′-bis(3-methylphenyl)-(1, l′-biphenyl)-4,4″-diamine (TPD), bis(3-methylphenyl)-N,N′-bis(phenyl)-spiro (spiro-TPD), N,N′-bis(4-(N,N′-diphenyl-amino) phenyl)-N,N′-diphenyl benzidine (DNTPD), 4,4′,4′-tris(N-carbazolyl)-triphenylamine (TCTA), tris(3-methylphenylphenylamino)-triphenylamine (m-MTDATA), poly [(9,9′-dioctylfluoren-2,7-diyl)-co-(4,4′-(N-(4-sec-butylphenyl) diphenylamine))] (TFB) and poly(4-butylphenyl-diphenylamine) (poly-TPD), or combinations thereof. The poly(p)phenylene vinylene and derivatives thereof includes poly(phenylene vinylide) (PPV), poly [2-methoxy-5-(2-ethylhexoxy)-1,4-phenylene vinylide] (MEH-PPV), poly [2-methoxy-5-(3′,7′-dimethyloctyloxy)-1,4-phenylene vinylide] (MOMO-PPV), or combinations thereof.

Specifically, the electron transport layer 16 may be formed of an inorganic material and/or an organic material. When the electron transport layer 16 is formed of the inorganic material, the electron transport layer 16 may be formed of the inorganic material selected from a group consisting of an undoped metal/non-metal oxide, a doped metal/non-metal oxide, an undoped semiconductor particle, a doped semiconductor particle, and a nitride. The doped metal/non-metal oxide is doped with Al, Mg, In, Li, Ga, Cd, Cs or Cu. The doped semiconductor particle is doped with Al, Mg, In, Li, Ga, Cd, Cs or Cu. For example, the metal/non-metal oxide may be TiO₂, ZnO, ZrO, SnO₂, WO₃, Ta₂O₃, HfO₃, Al₂O₃, ZrSiO₄, BaTiO₃ and BaZrO₃. For example, the semiconductor particle may be CdS, ZnSe and ZnS. The nitride may be Si₃N₄. When the electron transport layer 16 is formed of the organic material, it may be formed of an organic material such as an oxazole compound, an isoxazole compound, a triazole compound, an isothiazole compound, an oxadiazole compound, a thiadiazole compound, a perylene compound, or an aluminum complex.

Specifically, the cathode 17 is formed of a conductive material having a relatively low work function, which may be Ca, Ba, Ca/Al, LiF/Ca, LiF/Al, BaF₂/Al, CsF/Al, CaCO₃/Al, BaF₂/Ca/Al, Al, Mg, Au:Mg, or Ag:Mg.

In the embodiments of the present disclosure, a thickness of the anode 12 is 20 nm to 200 nm. A thickness of the hole injection layer 13 is 20 nm to 200 nm. A thickness of the hole transport layer 14 is 30 nm to 180 nm. A total thickness of the quantum dot light-emitting layer 15 is 30 nm to 180 nm. A thickness of the electron transport layer 16 is 10 nm to 180 nm. A thickness of the cathode 17 is 40 nm to 190 nm.

In the embodiments of the present disclosure, an external quantum efficiency of a first quantum dot light-emitting diode prepared by the first quantum dot alone is between 10% and 22%, and a measured lifetime of the first quantum dot light-emitting diode at a brightness of 1000 nit is 0 to 1 h. A measured lifetime of a second quantum dot light-emitting diode prepared by the second quantum dot at the brightness of 1000 nit is 1 h to 20 h, preferably 3 h to 10 h.

Specifically, the first quantum dot or the second quantum dot of the quantum dot light-emitting layer 15 is independently selected from at least one of group II-VI compound, group III-V compound, and group IV-VI compound. The group II-VI compound is selected from at least one of CdS, CdSe, CdTe, ZnS, ZnSe, ZnTe, ZnSeS, CdSeTe, CdSTe, ZnSeS, ZnSeTe, ZnSTe, ZnSeS, ZnSeTe, ZnSTe, CdZnTe, CdZnSeS, CdZnSeS, CdZnSeTe, HgZnTe, CdZnSeS, HgZnSeTe, HgZnTe, HdZnSeS, HgZnSeTe, HgZnSeTe, and HgZnTe. The group III-V compound is selected from at least one of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AIPAS, InNSb, InPAs, InPSb, InPAs, InPSb, GaAINP, GaAlNAs, GaAINSb, GaInPAs, GaInNSb, GaInNAs, GaInNSb, GalnPAs, GaInPSb, GalnPAs, GalInPSb, GalnPAs, GaInPSb, GalnPAs, GaInPSb, GalnPAs, GaInPSb, GalnPAs, GaInPSb, InAINP, InAINAs, GaInPSb, InAINAs, InAINAs, InAINAs, InAINSb, InAINAs, InAINSb, InAINAs, InAINSb, InAINAs, and InAINSb. The group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. A material of the first quantum dot and a material of the second quantum dot is different.

Furthermore, the first quantum dot light-emitting diode has a high external quantum efficiency, the external quantum efficiency is an important indicator to measure the luminescence performance of a diode, and the index reflects a process of charge injection into the quantum dot layer and formation of excitons during the operation of the quantum dot light-emitting diode 10. There are many factors affecting the external quantum efficiency, such as a quality of quantum dot, an energy level barrier size of charge transport layer and quantum dot layer, a thickness of each functional layer, the degradation of functional layer material, etc. For the types of quantum dots listed in the present disclosure, in theory, as long as the quality of synthesized quantum dots is high enough and matches the energy level of the charge transport layer, the external quantum efficiency of the quantum dot light-emitting diode can reach a theoretical limit of 25%. However, due to a limited selection of charge materials, and the difficulty in preparing high-quality quantum dots in some cases, so it is not specific here. It only needs to meet the requirement that the EQE of a quantum dot light-emitting diode reaches 10˜22% when the quantum dot light-emitting diode is prepared by the quantum dot alone, which can be regarded as high efficiency. In theory, all types of quantum dots listed in the present disclosure are feasible.

Furthermore, the second quantum dot light-emitting diode has a high lifetime. The lifetime is a key performance indicator to measure whether the quantum dot light-emitting diode 10 can be industrialized. Nowadays, the development of quantum dot light-emitting diodes 10 is at a critical stage of improving the lifetime, however, since there is no unified understanding of the mechanism of quantum dot light-emitting diode aging and decay, the development of the lifetime of quantum dot light-emitting diode 10 still has a long way to go. There are multiple factors that affect the lifetime of the quantum dot light-emitting diode 10, which are not only related to the stability of the quantum dot itself, but also have an important relationship with degradation of functional layer material, and charge accumulation/leakage and Joule heat caused by unbalanced charge injection. Therefore, different quantum dot materials can theoretically achieve a higher lifetime when matched with appropriate types of functional layers. However, there are many problems such as the quality of the quantum dots and the selection of functional layers, the lifetime of the quantum dot light-emitting diode, especially the lifetime of a blue quantum dot light-emitting diode 10, still cannot be effectively solved. In theory, all types of quantum dots listed in the article can be selected.

In the embodiments of the present disclosure, a luminescence wavelength of the first quantum dot and a luminescence wavelength of the second quantum dot are in a same wavelength band, and an energy band width of the first quantum dot and an energy band width of the second quantum dot are the same. The energy band width refers to an energy range between a lowest energy level and a highest energy level in an energy band.

Furthermore, by setting the luminescence wavelength of the first quantum dot and the luminescence wavelength of the second quantum dots in a same wavelength band, luminescence wavelengths of the light emitted by the quantum dot film prepared by mixing the first quantum dot and the second quantum dot can be within a same wavelength range. The energy band width of the first quantum dot and the energy band width of the second quantum dot are set to be the same in order to make it easier for the first ligand to stake first excitons generated by the first quantum dot with second excitons generated by the second quantum dot (an energy range of a exciton movement is within the energy band width).

Furthermore, a mass ratio of the first quantum dot to the second quantum dot ranges from 1:10 to 1:1. The first quantum dot and the second quantum dot are mixed to form a film. A method of forming the film includes coating, spraying, ink jet printing and the like.

In the embodiments of the present disclosure, the first ligand is an exciton delocalized ligand. The exciton delocalized ligand is a type of ligand having a leading molecular orbital that strongly engages with the edge state of a quantum dot band. The exciton delocalized ligand can promote a diffusion of the carrier wave function outside the quantum dot, to have excitons inside the quantum dot radiates to the edge state of the quantum dot band, thereby enhancing a coupling effect between the exciton of the quantum dot and neighboring molecules. The exciton delocalized ligand is configured to couple the first excitons generated from the surface of the first quantum dot with high external quantum efficiency and the second excitons generated from the surface of the second quantum dot with high measured lifetime, thus to have the first excitons to stacke with the second excitons. The stacking effect between the first excitons and the second excitons makes the device of the whole mixed system of quantum dots have advantages of two different types of quantum dots, thereby the quantum dot light-emitting diode 10 prepared by the quantum dot light-emitting layer 15 that is finally mixed has an indicator of high efficiency and high lifetime.

Furthermore, a mass of quantum dot ligands in the quantum dot light-emitting layer 15 generally accounts for about 20% of the total mass of the quantum dot light-emitting layer 15. The first ligand is one type of the quantum dot ligands, and a mass percentage of the first ligand in the quantum dot light-emitting layer 15 is about 2% to 15%, and another quantum dot ligands are conventional ligands. The conventional ligands include at least one of C₅ to C₃₀ saturated or unsaturated fatty acids, C₅ to C₃₀ linear or branched alkyl mercaptans, C₁ to C₂₀ linear or branched alkyl amines, and C₁ to C₂₀ linear or branched alkyl phosphines.

In the embodiments of the present disclosure, on one aspect, the conventional ligand has a function of stabilizing a core and a shell of the quantum dot film, and on another aspect, the conventional ligand has a function of improving an ability of the core and the shell of the quantum dot film to dissolve or disperse in an organic solvent. Preferably, the mass percentage of the first ligand in the quantum dot light-emitting layer 15 is between 2% and 8%. A number of the first ligand can be obtained by controlling an amount of the first ligand during exchange, and a specific ligand content can be obtained by performing thermogravimetric analysis tests and combining infrared on the quantum dots after each exchange. Furthermore, the mass percentage of the first ligand in the quantum dot light-emitting layer 15 is no more than 8%. If the mass percentage of the first ligand in the quantum dot light-emitting layer 15 is more than 8%, an exciton degree of the quantum dot itself may be too high, and the delocalization amplitude of the exciton may be too large, which not only an optical band gap red shift amplitude of the quantum dot itself is too large, but also the delocalization exciton may be easily affected by the external environment to cause the risk of quenching. Moreover, the mass percentage of the first ligand in the quantum dot light-emitting layer 15 is no less than 2%. If the mass percentage of the first ligand in the quantum dot light-emitting layer 15 is less than 2%, the exciton delocalization degree of the quantum dot itself is too small, and the excitons between different types of quantum dots are not easy to be stacked, so that it is difficult to balance the contradiction between high efficiency and high measured lifetime of the quantum dot light-emitting diode.

In the embodiments of the present disclosure, the first ligand includes but is not limited to phenyl dithiocarbamate (PDTC), 1,3-dimethyl-4,5-disubstituted imidazole subunit N-heterocyclic carbene (NHC), and the like. The preparation of the first ligand can be carried out by ligand exchange using a prior art, and the exchange method thereof will not be described here.

Furthermore, the quantum dot light-emitting layer 15 formed by mixing has following beneficial effects: the first ligand has a leading molecular orbital strongly bonded to the edge state of the quantum dot band, can promote the diffusion of the carrier wave function outside the quantum dot, and can enhance the coupling effect of the quantum dot exciton and the neighboring molecules. When the first quantum dot with high external quantum efficiency, the second quantum dot with high measured lifetime and the first ligand are mixed, the excitons delocalized to the surface of the two different types of quantum dots are stacked to a certain extent under the action of the first ligand. The stacking effect between the excitons makes the device of the whole mixed system of quantum dots have advantages of the two different types of quantum dots, showing that the device has both high efficiency and high measured lifetime. To a certain extent, the problem that the high efficiency and high measured lifetime of conventional devices are contradicted is solved, thereby improving the performance of the quantum dot light-emitting diode.

Correspondingly, the embodiments of the present application also provide a preparation method for the quantum dot light-emitting diode 10. Referring to FIG. 2. FIG. 2 is a flowchart of a preparation method for a quantum dot light-emitting diode according to an embodiment of the present disclosure. Specifically, the method includes:
Step S11: providing a first electrode;
Step S12: forming a quantum dot film on the first electrode, and thermally annealing to form a quantum dot light-emitting layer;
Step S13: forming a second electrode on the quantum dot light-emitting layer.

Moreover, the quantum dot film includes quantum dots, surfaces of at least part of the quantum dots are connected with a first ligand. The quantum dots include a first quantum dot and a second quantum dot. The first ligand is configured to stack first excitons generated by the first quantum dot with second excitons generated by the second quantum dot.

In one embodiment, the preparation method for the quantum dot light-emitting diode 10 includes:
Preparing an anode 12 on a substrate 11;
Preparing a hole injection layer 13 on the anode 12;
Preparing a hole transport layer 14 on the hole injection layer 13;
Preparing a quantum dot light-emitting layer 15 on the hole transport layer 14;
Preparing an electron transport layer 16 on the quantum dot light-emitting layer 15;
Preparing a cathode 17 on the electron transport layer 16.

Moreover, the quantum dot light-emitting layer 15 includes a first quantum dot, a second quantum dot, and a first ligand connected to the first quantum dot and/or the second quantum dot.

Moreover, an external quantum efficiency of a first quantum dot light-emitting diode prepared by the first quantum dot alone is greater than or equal to 10% and less than or equal to 22% (between 10% and 22%), and a measured lifetime of a second quantum dot light-emitting diode prepared by the second quantum dot at the brightness of 1000 nit is between 1 h and 20 h. The first ligand is configured to stacked first excitons generated by the first quantum dot with second excitons generated by the second quantum dot.

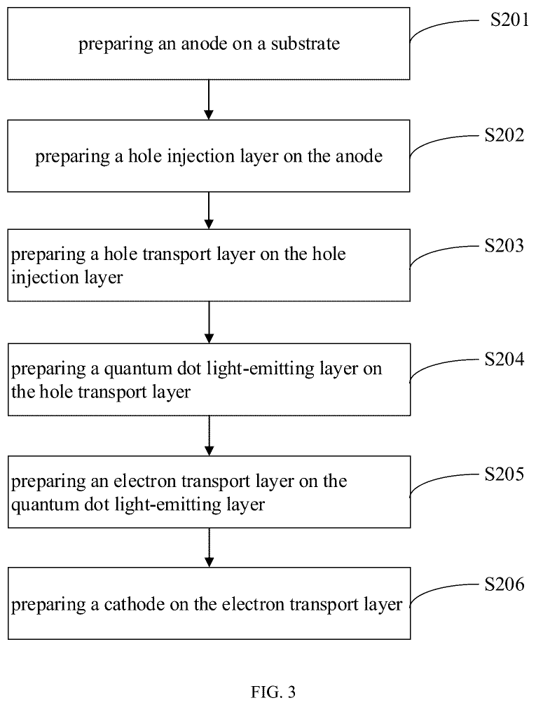

Referring to FIG. 3, FIG. 3 is a flowchart of a preparation method for a quantum dot light-emitting device according to another embodiment of the present disclosure. Specifically, the preparation method includes:
S201, preparing an anode 12 on a substrate 11.

Specifically, the S201 further includes:
Depositing a layer of metal layer on the substrate 11, and patterning the metal layer to form an anode 12. A method of depositing the anode 12 may be selected from vacuum evaporation and sputtering. The substrate 11 includes a steel substrate or a flexible substrate, and specifically includes glass, silicon wafer, polycarbonate, polymethyl methacrylate, polyethylene terephthalate, polyethylene naphthalate, polyamide, polyethersulfone, or combinations thereof. Moreover, the anode 12 is formed of a conductive material having a relatively high work function, which may be formed of a doped metal oxide or an undoped metal oxide, such as ITO, IZO, ITZO, ICO, SnO₂, In₂O₃, Cd:ZnO, F:SnO₂, In:SnO₂, Ga:SnO₂, AZO, and the like. In addition to the doped metal oxide and the undoped metal oxide, the anode 12 may be formed of a metal material including nickel (Ni), platinum (Pt), gold (Au), silver (Ag), iridium (Ir), or carbon nanotubes (CNT).

S202, preparing a hole injection layer 13 on the anode 12.

Specifically, the S202 further includes:
Preparing a hole injection layer 13 on the anode 12. A method of depositing the hole injection layer 13 may be selected from solution method and vacuum evaporation. A material of the hole implanted layer 13 includes poly (ethylene dioxythiophene):polystyrene sulfonate (PEDOT:PSS), poly (9,9-dioctyl-fluorene-co-N-(4-butylphenyl)-diphenylamine) (TFB), polyarylamine, poly(N-vinylcarbazole), polyaniline, polypyrrole, N,N′,N′-tetrakis (4-methoxyphenyl)-benzidine (TPD), 4-bis [N-(1-naphthyl)-N-phenyl-amino] biphenyl (α-NPD), 4,4′,4″-tri[phenyl(m-tolyphenyl) amino] triphenylamine (m-MTDATA), 4,4′,4″-tri (N-carbazolyl) triphenylamine (TCTA), 4,4′-cyclohexylbis [N,N-bis(4-methylphenyl)] aniline (TAPC), 4,4′4″-Tris(N,N-diphenylamino)triphenylamine (TDATA) doped with tetrafluoro-tetracyanoquinone dimethane (F4-TCNQ), p-doped phthalocyanines (e.g., F4-TCNQ-doped zinc phthalocyanine (ZnPc)), F4-TCNQ-doped N,N-diphenyl-N,N-bis(1-naphthyl)-1,1-biphenyl-4,4″-diamine (α-NPD), and hexaaza-benzphenanthrene-hexanthrene (HAT-CN).

S203, preparing a hole transport layer 14 on the hole injection layer 13.

Specifically, the S203 further includes:
Preparing a hole transport layer 14 on the hole injection layer 13. A method of depositing the hole transport layer 14 may be selected from solution method and vacuum evaporation. When the hole transport layer 14 includes an organic material, the organic material includes an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, PEDOT:PSS and derivatives thereof, poly(N-vinyl carbazole) (PVK) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine (NPB), spiro-NPB, or combinations thereof. The aryl amine includes 4,4′-N,N′-diphenyl-N,N′-bis (1-naphthyl)-1,1′-biphenyl-4,4″-diamine (α-NPD), N,N′-bis(3-methylphenyl)-(1, 1′-biphenyl)-4,4″-diamine (TPD), bis(3-methylphenyl)-N,N′-bis(phenyl)-spiro (spiro-TPD), N,N′-bis(4-(N,N′-diphenyl-amino) phenyl)-N,N′-diphenyl benzidine (DNTPD), 4,4′,4′-tris(N-carbazolyl)-triphenylamine (TCTA), tris(3-methylphenylphenylamino)-triphenylamine (m-MTDATA), poly [(9,9′-dioctylfluoren-2,7-diyl)-co-(4,4′-(N-(4-sec-butylphenyl) diphenylamine))] (TFB) and poly (4-butylphenyl-diphenylamine) (poly-TPD), or combinations thereof. The poly(p)phenylene vinylene and derivatives thereof includes poly(phenylene vinylide) (PPV), poly [2-methoxy-5-(2-ethylhexoxy)-1,4-phenylene vinylide] (MEH-PPV), poly [2-methoxy-5-(3′,7′-dimethyloctyloxy)-1,4-phenylene vinylide] (MOMO-PPV), or combinations thereof.

S204, preparing a quantum dot light-emitting layer 15 on the hole transport layer 14.

Specifically, the S204 further includes:
Firstly, coating a quantum dot ink on an upper surface of the hole transport layer 14. A method of coating includes spin coating, scratch coating, ink jet printing, and the like. The quantum dot ink includes a first type of quantum dot ink, a second type of quantum dot ink, and a first ligand. The first type of quantum dot ink is configured to form a first quantum dot, and the second type of quantum dot ink is configured to form a second quantum dot.
Secondly, placing the quantum dot ink for a period of time, and then drying to form a quantum dot film. Specifically: placing a wet film formed by the quantum dot ink in a normal pressure environment for 2 minutes to 10 minutes, then transferring it to a vacuum chamber, drying it in a decompressed environment, thus to form the quantum dot film. When the quantum dot film is placed under a normal pressure, its temperature can be controlled between 10° C. and 35° C.

Finally, thermally annealing the quantum dot film to form a quantum dot light-emitting layer 15. A thermal annealing temperature of the quantum dot film is between 50° C. and 120° C., and a time of the thermally annealing is between 5 minutes and 30 minutes.

S205, preparing an electron transport layer 16 on the quantum dot light-emitting layer 15.

Specifically, the S205 further includes:
Forming an electron transport layer 16 on the quantum dot light-emitting layer 15 by a solution method. A process of forming the electron transport layer 16 by the solution method may include operations such as coating of solution, drying, and annealing of the film have been dried. A coating method of the solution method includes spin coating, scratch coating, ink jet printing, and the like.

Specifically, the electron transport layer 16 may be formed of an inorganic material and/or an organic material. When the electron transport layer 16 is formed of the inorganic material, the electron transport layer 16 may be formed of the inorganic material selected from a group consisting of an undoped metal/non-metal oxide, a doped metal/non-metal oxide, an undoped semiconductor particle, a doped semiconductor particle, and a nitride. The doped metal/non-metal oxide is doped with Al, Mg, In, Li, Ga, Cd, Cs or Cu. The doped semiconductor particle is doped with Al, Mg, In, Li, Ga, Cd, Cs or Cu. For example, the metal/non-metal oxide may be TiO₂, ZnO, ZrO, SnO₂, WO₃, Ta₂O₃, HfO₃, Al₂O₃, ZrSiO₄, BaTiO₃ and BaZrO₃. For example, the semiconductor particle may be CdS, ZnSe and ZnS. The nitride may be Si₃N₄. When the electron transport layer 16 is formed of the organic material, it may be formed of an organic material such as an oxazole compound, an isoxazole compound, a triazole compound, an isothiazole compound, an oxadiazole compound, a thiadiazole compound, a perylene compound, or an aluminum complex.

S206, preparing a cathode 17 on the electron transport layer 16.

Specifically, the S206 further includes:
Preparing a cathode 17 on the electron transport layer 16. A method of depositing the cathode 17 may be selected from vacuum evaporation and sputtering. The cathode 17 is formed of a conductive material having a relatively low work function, which may be Ca, Ba, Ca/Al, LiF/Ca, LiF/Al, BaF₂/Al, CsF/Al, CaCO₃/Al, BaF₂/Ca/Al, Al, Mg, Au:Mg or Ag:Mg.

Specifically, 12 different kinds of quantum dot light-emitting diodes 10 are prepared according to the preparation method for the quantum dot light emitting diode 10 above. After the preparation of the quantum dot light emitting diode 10 device is completed, the quantum dot light-emitting diodes 10 is heat treated at 120° C. for 15 minutes. Then, subsequent performance characterization is performed on the quantum dot light-emitting diodes 10 after completing the heat treatment.

Furthermore, film layer structures of the 12 different kinds of quantum dot light-emitting diodes 10 from the substrate 11 to the cathode 17 are shown as follows:

### Example 1

A quantum dot light-emitting diode 10 (QLED 1) provided in the Example 1 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 40 nm;
A hole transport layer 14 with materials of TFB and PVK, and a thickness of the hole transport layer 14 is 60 nm;
A quantum dot light-emitting layer 15 which is:
a mixed layer of CdₓZn₁₋ₓS/Cd_{y}Zn_{1-y}S/ZnS and CdₓZn₁₋ₓSe/Cd_{y}Zn_{1-y}Se/CdZnS (0<x<1, 0<y<1, x>y), a thickness of the mixed layer is 30 nm, and a mass ratio of the CdₓZn₁₋ₓS/Cd_{y}Zn_{1-y}S/ZnS to the CdₓZn₁₋ₓSe/Cd_{y}Zn_{1-y}Se/CdZnS is 1:1;

A first ligand on surfaces of the two types of quantum dots is phenyl dithiocarbamate (PDTC), and a content of the first ligand is 5%;

An electron transport layer 16 is made of ZnO, and a thickness of the electron transport layer 16 is 70 nm; and

A top electrode is made of Ag, and a thickness of the top electrode is 50 nm.

### Comparative Example 1-1

A quantum dot light-emitting diode 10 (QLED 1-1) prepared by the Comparative Example 1-1 compared with the Example 1 of the present disclosure includes:
A substrate 11 which is a glass substrate;
An anode 12 is made of ITO, and a thickness of the anode 12 is 90 nm;
A hole injection layer 13 is made of PEDOT:PSS, and a thickness of the hole injection layer 13 is 40 nm;
A hole transport layer 14 is made of PVK, and a thickness of the hole transport layer 14 is 50 nm;
A quantum dot light-emitting layer 15 which is a mixed layer of CdₓZn₁₋ₓS/Cd_{y}Zn_{1-y}S/ZnS (0<x<1, 0<y<1, x>y), a luminescence wavelength of the quantum dot light-emitting layer 15 is 471 nm, a thickness of the quantum dot light-emitting layer 15 is 30 nm, and a peak width of the quantum dot light-emitting layer 15 is 22 nm;
An electron transport layer 16 is made of ZnO, and a thickness of the electron transport layer 16 is 80 nm; and
A top electrode is made of Ag, and a thickness of the top electrode is 50 nm.

### Comparative Example 1-2

A quantum dot light-emitting diode 10 (QLED 1-2) prepared by the Comparative Example 1-2 compared with the Example 1 of the present disclosure includes:
A substrate 11 which is a glass substrate;
An anode 12 is made of ITO, and a thickness of the anode 12 is 90 nm;
A hole injection layer 13 is made of PEDOT:PSS, and a thickness of the hole injection layer 13 is 60 nm;
A hole transport layer 14 is made of TFB, and a thickness of the hole transport layer 14 is 50 nm;
A quantum dot light-emitting layer 15 which is a mixed layer of CdₓZn₁₋ₓSe/CdyZn_{1-y}Se/CdZnS (0<x<1, 0<y<1, x>y), a luminescence wavelength of the quantum dot light-emitting layer 15 is 471 nm, a thickness of the quantum dot light-emitting layer 15 is 20 nm, and a peak width of the quantum dot light-emitting layer 15 is 20 nm;
An electron transport layer 16 is made of ZnO, and a thickness of the electron transport layer 16 is 80 nm; and
A top electrode is made of Ag, and a thickness of the top electrode is 50 nm.

### Example 2

A quantum dot light-emitting diode 10 (QLED 2) provided in the Example 2 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 40 nm;
A hole transport layer 14 with materials of TFB and PVK, and a thickness of the hole transport layer 14 is 60 nm;
A quantum dot light-emitting layer 15 which is:
a mixed layer of CdₓZn₁₋ₓS/Cd_{y}Zn_{1-y}S/ZnS and CdₓZn₁₋ₓSe/CdyZn_{1-y}Se/CdZnS (0<x<1, 0<y<1, x>y), a thickness of the mixed layer is 30 nm, and a mass ratio of the CdₓZn₁₋ₓS/Cd_{y}Zn_{1-y}S/ZnS to the CdₓZn₁₋ₓSe/Cd_{y}Zn_{1-y}Se/CdZnS is 1:1;
A first ligand on surfaces of the two types of quantum dots is phenyl dithiocarbamate (PDTC), and a content of the first ligand is 5%;
An electron transport layer 16 is made of ZnO, and a thickness of the electron transport layer 16 is 70 nm; and
A top electrode is made of Ag, and a thickness of the top electrode is 50 nm.

### Comparative Example 2-1

A quantum dot light-emitting diode 10 (QLED 2-1) prepared by the Comparative Example 2-1 compared with the Example 2 of the present disclosure includes:
A substrate 11 which is a glass substrate;
An anode 12 is made of ITO, and a thickness of the anode 12 is 90 nm;
A hole injection layer 13 is made of PEDOT:PSS, and a thickness of the hole injection layer 13 is 40 nm;
A hole transport layer 14 is made of PVK, and a thickness of the hole transport layer 14 is 50 nm;
A quantum dot light-emitting layer 15 which is a mixed layer of CdₓZn₁₋ₓS/Cd_{y}Zn_{1-y}S/ZnS (0<x<1, 0<y<1, x>y), a luminescence wavelength of the quantum dot light-emitting layer 15 is 475 nm, a thickness of the quantum dot light-emitting layer 15 is 20 nm, and a peak width of the quantum dot light-emitting layer 15 is 19 nm;
An electron transport layer 16 is made of ZnO, and a thickness of the electron transport layer 16 is 80 nm; and
A top electrode is made of Ag, and a thickness of the top electrode is 50 nm.

### Comparative Example 2-2

A quantum dot light-emitting diode 10 (QLED 2-2) prepared by the Comparative Example 2-2 compared with the Example 2 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 70 nm;
A hole transport layer 14 is made of TFB, and a thickness of the hole transport layer 14 is 50 nm;
A quantum dot light-emitting layer 15 which is a mixed layer of CdₓZn₁₋ₓSe/Cd_{y}Zn_{1-y}Se/CdZnS (0<x<1, 0<y<1, x>y), a luminescence wavelength of the quantum dot light-emitting layer 15 is 475 nm, a thickness of the quantum dot light-emitting layer 15 is 20 nm, and a peak width of the quantum dot light-emitting layer 15 is 23 nm;
An electron transport layer 16 is made of ZnO, and a thickness of the electron transport layer 16 is 50 nm; and
A top electrode is made of Ag, and a thickness of the top electrode is 50 nm.

### Example 3

A quantum dot light-emitting diode 10 (QLED 3) provided in the Example 3 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 40 nm;
A hole transport layer 14 with materials of TFB and PVK, and a thickness of the hole transport layer 14 is 70 nm;
A quantum dot light-emitting layer 15 which is:
a mixed layer of CdₓZn₁₋ₓS/Cd_{y}Zn_{1-y}S/ZnS and CdₓZn₁₋ₓSe/Cd_{y}Zn_{1-y}Se/CdZnS (0<x<1, 0<y<1, x>y), a thickness of the mixed layer is 30 nm, and a mass ratio of the CdₓZn₁₋ₓS/Cd_{y}Zn_{1-y}S/ZnS to the CdₓZn₁₋ₓSe/Cd_{y}Zn_{1-y}Se/CdZnS is 1:1;
A first ligand on surfaces of the two types of quantum dots is phenyl dithiocarbamate (PDTC), and a content of the first ligand is 3%;
An electron transport layer 16 is made of ZnMgO (a content of Mg is 15%), and a thickness of the electron transport layer 16 is 50 nm; and
A top electrode is made of Ag, and a thickness of the top electrode is 50 nm.

### Comparative Example 3-1

A quantum dot light-emitting diode 10 (QLED 3-1) prepared by the Comparative Example 3-1 compared with the Example 3 of the present disclosure includes:
A substrate 11 which is a glass substrate;
An anode 12 is made of ITO, and a thickness of the anode 12 is 90 nm;
A hole injection layer 13 is made of PEDOT:PSS, and a thickness of the hole injection layer 13 is 40 nm;
A hole transport layer 14 is made of PVK, and a thickness of the hole transport layer 14 is 50 nm;
A quantum dot light-emitting layer 15 which is a mixed layer of CdₓZn₁₋ₓS/Cd_{y}Zn_{1-y}S/ZnS (0<x<1, 0<y<1, x>y), a luminescence wavelength of the quantum dot light-emitting layer 15 is 465 nm, a thickness of the quantum dot light-emitting layer 15 is 20 nm, and a peak width of the quantum dot light-emitting layer 15 is 22 nm;
An electron transport layer 16 is made of ZnO, and a thickness of the electron transport layer 16 is 60 nm; and
A top electrode is made of Ag, and a thickness of the top electrode is 50 nm.

### Comparative Example 3-2

A quantum dot light-emitting diode 10 (QLED 3-2) prepared by the Comparative Example 3-2 compared with the Example 3 of the present disclosure includes:
A substrate 11 which is a glass substrate;
An anode 12 is made of ITO, and a thickness of the anode 12 is 70 nm;
A hole injection layer 13 is made of PEDOT:PSS, and a thickness of the hole injection layer 13 is 60 nm;
A hole transport layer 14 is made of TFB, and a thickness of the hole transport layer 14 is 60 nm;
A quantum dot light-emitting layer 15 which is a mixed layer of CdₓZn₁₋ₓSe/Cd_{y}Zn_{1-y}Se/CdZnS (0<x<1, 0<y<1, x>y), a luminescence wavelength of the quantum dot light-emitting layer 15 is 465 nm, a thickness of the quantum dot light-emitting layer 15 is 20 nm, and a peak width of the quantum dot light-emitting layer 15 is 20 nm;
An electron transport layer 16 is made of ZnMgO (a content of Mg is 15%), and a thickness of the electron transport layer 16 is 60 nm; and
A top electrode is made of Ag, and a thickness of the top electrode is 50 nm.

### Example 4

A quantum dot light-emitting diode 10 (QLED 4) provided in the Example 4 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 40 nm;
A hole transport layer 14 with materials of TFB and PVK, and a thickness of the hole transport layer 14 is 60 nm;
A quantum dot light-emitting layer 15 which is:
a mixed layer of CdₓZn₁₋ₓS/CdyZn_{1-y}S/ZnS and CdₓZn₁₋ₓSe/Cd_{y}Zn_{1-y}Se/CdZnS (0<x<1, 0<y<1, x>y), a thickness of the mixed layer is 30 nm, and a mass ratio of the CdₓZn₁₋ₓS/Cd_{y}Zn_{1-y}S/ZnS to the CdₓZn₁₋ₓSe/Cd_{y}Zn_{1-y}Se/CdZnS is 1:1;
A first ligand on surfaces of the two types of quantum dots is phenyl dithiocarbamate (PDTC), and a content of the first ligand is 5%;
An electron transport layer 16 with materials of ZnO and ZnMgO (a content of Mg is 15%), and a thickness of the electron transport layer 16 is 60 nm; and
A top electrode is made of Ag, and a thickness of the top electrode is 50 nm.

### Comparative Example 4-1

A quantum dot light-emitting diode 10 (QLED 4-1) prepared by the Comparative Example 4-1 compared with the Example 4 of the present disclosure includes:
A substrate 11 which is a glass substrate;
An anode 12 is made of ITO, and a thickness of the anode 12 is 90 nm;
A hole injection layer 13 is made of PEDOT:PSS, and a thickness of the hole injection layer 13 is 40 nm;
A hole transport layer 14 is made of PVK, and a thickness of the hole transport layer 14 is 50 nm;
A quantum dot light-emitting layer 15 which is a mixed layer of CdₓZn₁₋ₓS/Cd_{y}Zn_{1-y}S/ZnS (0<x<1, 0<y<1, x>y), a luminescence wavelength of the quantum dot light-emitting layer 15 is 468 nm, a thickness of the quantum dot light-emitting layer 15 is 20 nm, and a peak width of the quantum dot light-emitting layer 15 is 18 nm;
An electron transport layer 16 is made of ZnO, and a thickness of the electron transport layer 16 is 80 nm; and
A top electrode is made of Ag, and a thickness of the top electrode is 50 nm.

### Comparative Example 4-2

A quantum dot light-emitting diode 10 (QLED 4-2) prepared by the Comparative Example 4-2 compared with the Example 4 of the present disclosure includes:
A substrate 11 which is a glass substrate;
An anode 12 is made of ITO, and a thickness of the anode 12 is 80 nm;
A hole injection layer 13 is made of PEDOT:PSS, and a thickness of the hole injection layer 13 is 70 nm;
A hole transport layer 14 is made of TFB, and a thickness of the hole transport layer 14 is 50 nm;
A quantum dot light-emitting layer 15 which is a mixed layer of CdₓZn₁₋ₓSe/Cd_{y}Zn_{1-y}Se/CdZnS (0<x<1, 0<y<1, x>y), a luminescence wavelength of the quantum dot light-emitting layer 15 is 468 nm, a thickness of the quantum dot light-emitting layer 15 is 20 nm, and a peak width of the quantum dot light-emitting layer 15 is 20 nm;
An electron transport layer 16 is made of ZnMgO (a content of Mg is 10%), and a thickness of the electron transport layer 16 is 50 nm; and
A top electrode is made of Ag, and a thickness of the top electrode is 50 nm.

Finally, maximum external quantum efficiency and measured lifetime of the above-mentioned 12 kinds of quantum dot light-emitting diodes 10 are tested, and the performance results of the quantum dot light-emitting diodes 10 are shown in Table 1:

TABLE 1

| | EQEₘₐₓ (%) | T95_{1000 nit} (h) |
|---|---|---|
| Comparative Example 1-1 | 16 | 0.1 |
| Comparative Example 1-2 | 6 | 3.4 |
| Example 1 | 13 | 2.3 |
| Comparative Example 2-1 | 18 | 0.2 |
| Comparative Example 2-2 | 5 | 2.8 |
| Example 2 | 12 | 2.5 |
| Comparative Example 3-1 | 15 | 0.03 |
| Comparative Example 3-2 | 3 | 1.8 |
| Example 3 | 8.5 | 1.1 |
| Comparative Example 4-1 | 15 | 0.05 |
| Comparative Example 4-2 | 4 | 2.1 |
| Example 4 | 9.6 | 1.2 |

In Table 1, EQEmax is the maximum external quantum efficiency of the quantum dot light-emitting diode 10, and T951000 nit is the time when the brightness of the quantum dot light-emitting diode 10 drops to 95% of the maximum brightness at 1000 nit brightness. Test performance of the quantum dot light-emitting diodes 10 prepared in the Comparative Example 1 to 4 and Examples 1 to 4, and a test method is as follows:

(1) External quantum efficiency: a ratio of the number of electrons-holes injected into the quantum dot to the number of emitted photons, a unit of the external quantum efficiency is %, the external quantum efficiency is an important parameter to measure the pros and cons of electroluminescent devices, and can be measured by EQE optical testing instrument. A specific calculation formula is as follows:

$$EQE = η e η r χ * KR / ( KR + KNR ) ;$$

In the formula, ηe is a coupling efficiency of optical output, ηr is a ratio of the number of recombined carriers to the number of injected carriers, χ is a ratio of the number of excitons generating photons to a total number of excitons, KR is a rate of the radiative process, and KNR is a rate of the non-radiative process.

Test conditions: At room temperature, and the air humidity is 30˜60%.

(2) Life time of the quantum dot light-emitting diode: a time required for the quantum dot light-emitting diode to reduce its brightness to a certain proportion of the highest brightness under the constant current or constant voltage drive. The time when the brightness drops to 95% of the highest brightness is defined as T95, and this lifetime is the measured lifetime. In order to shorten the test cycle, the device lifetime test is usually carried out with reference to the organic light-emitting diode test under high brightness through the aging of the accelerator device, and the lifetime under high brightness is fitted by the extended exponential decay brightness attenuation fitting formula, for example: the lifetime at 1000 nit is T951000 nit. A specific calculation formula is as follows:

$$T {95}_{L} = T {95}_{H} * {( {L}_{H} / {L}_{L} )}^{A} ;$$

In the formula, T951, is a lifetime under low brightness, T95H is a measured lifetime under high brightness, Lu is an acceleration of the device to the highest brightness of the device, L_{L} is 1000 nit, and A is an acceleration factor. For OLED, A is usually 1.6˜2. In this experiment, a lifetime of several groups of green QLED devices under rated brightness is measured, which gives an A value of 1.7.

Test conditions for the corresponding device lifetime testing by using the lifetime testing system are: at room temperature, and the air humidity is 30˜60%.

As can be seen from Table 1 above, comparing Example 1 with Comparative Example 1-1 and Comparative Example 1-2, it can be seen that the quantum dot light-emitting diode provided by Comparative Example 1-1 has a relatively high maximum external quantum efficiency and a relatively short measured lifetime, and the quantum dot light-emitting diode provided by Comparative Example 1-2 has a relatively long measured lifetime and a relatively low maximum external quantum efficiency. The maximum external quantum efficiency of the quantum dot light-emitting diode provided by Example 1 is between the maximum external quantum efficiency of the Comparative Example 1-1 and the Comparative Example 1-2, and the measured lifetime of the quantum dot light-emitting diode provided by Example 1 is between the Comparative Example 1-1 and the Comparative Example 1-2. Therefore, the quantum dot light-emitting diode provided by Example 1 has the characteristics of high external quantum efficiency and high measured lifetime because of the addition of the first ligand. Likewise, the quantum dot light-emitting diodes provided in Example 2, Example 3, and Example 4 are all like this, and will not be described here in detail.

Moreover, comparing Example 1 with Example 2, it can be seen that when the material and content of the first ligand are the same and other films are substantially the same, when the mass percentage of the first quantum dot having a relatively high maximum external quantum efficiency in the quantum dot light-emitting layer 15 in the total mass of the quantum dot light-emitting layer 15 is increased, the maximum external quantum efficiency of the prepared quantum dot light-emitting diode becomes smaller and the measured lifetime becomes longer.

Moreover, comparing Example 2 with Example 4, it can be seen that when the content of the first ligand in Example 2 is the same as that of the first ligand in Example 4, and other films are substantially the same, the maximum external quantum efficiency of the quantum dot light-emitting diode prepared when the material of the first ligand is phenyl dithiocarbamate is greater than that of the quantum dot light-emitting diode prepared when the material of the first ligand is 1,3-dimethyl-4,5-disubstituted imidazolyl subunit N-heterocyclic carbene. The measured lifetime of the quantum dot light-emitting diode prepared when the material of the first ligand is phenyl dithiocarbamate is higher than that of the quantum dot light-emitting diode prepared when the material of the first ligand is 1,3-dimethyl-4,5-disubstituted imidazole subunit N-heterocyclic carbene.

Moreover, comparing Example 3 with Example 4, it can be seen that when the material of the first ligand in Example 3 is the same as that of the first ligand in Example 4, and other films are substantially the same, the mass percentage of the first ligand in the quantum dot light-emitting layer 15 increases within a certain range, and at this time, the maximum external quantum efficiency and the measured lifetime of the prepared quantum dot light-emitting diode increase.

Moreover, comparing the Comparative Example 1-1 with the Comparative Example 3-1, it can be seen that the larger the luminescence wavelength of the first quantum dot is, the greater the maximum external quantum efficiency and the higher the measured lifetime of the first quantum dot in the case of other films are same.

Accordingly, the embodiments of the present disclosure further provide a display device including a quantum dot light-emitting diode 10 as described above.

In summary, the embodiments of the present disclosure provide a quantum dot film, a quantum dot light-emitting diode, a preparation method therefor, and a display device. The quantum dot film includes a first quantum dot, a second quantum dot, and a first ligand connected to the first quantum dot and/or the second quantum dot. The first ligand is configured to stack the first excitons generated by the first quantum dot with the second excitons generated by the second quantum dot. By adding the first ligand between the first quantum dot and the second quantum dot of the quantum dot film above, the first ligand can stack the first excitons generated by the first quantum dot and the second excitons generated by the second quantum dot. A stacking effect between the first excitons and the second excitons cause a part of the first excitons to follow the second excitons stacked with themselves to radiative recombination output into a core shell of the second quantum dot, and at a same time cause a part of the second excitons to follow the firse excitons stacked with themselves to radiative recombination output into a core shell of the first quantum dot, so that the first quantum dot and/or the second quantum dot possess both the first excitons and the second excitons, thereby making the quantum dots of the entire hybrid system possess advantages of two different types of quantum dots, thus to make the quantum dot light-emitting diode prepared by the above-mentioned quantum dot film possess characteristics of the first quantum dot light-emitting diode prepared by the first quantum dot alone and characteristics of the second quantum dot light-emitting diode prepared by the second quantum dot alone, thus further improving light emission performance of the quantum dot light-emitting diode.

The quantum dot light-emitting diode, preparation method therefor, and the display device according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

1. A quantum dot film, comprising:
quantum dots, surfaces of at least part of the quantum dots connected with a first ligand, and the quantum dots comprising a first quantum dot and a second quantum dot;
wherein, the first ligand is configured to stack first excitons generated by the first quantum dot with second excitons generated by the second quantum dot.

2. The quantum dot film according to claim 1, wherein an external quantum efficiency of a first quantum dot light-emitting diode prepared by the first quantum dot alone is greater than or equal to 10%, a measured lifetime of the first quantum dot light-emitting diode at a brightness of 1000 nit is less than or equal to 1 h, and a measured lifetime of a second quantum dot light-emitting diode prepared by the second quantum dot at the brightness of 1000 nit is between 1 h and 20 h.

3. The quantum dot film according to claim 2, wherein the external quantum efficiency of the first quantum dot light-emitting diode prepared by the first quantum dot alone is between 10% and 22%.

4. The quantum dot film according to claim 2, wherein the measured lifetime of the second quantum dot light-emitting diode prepared by the second quantum dot at the brightness of 1000 nit is between 3 h and 10 h.

5. The quantum dot film according to claim 1, wherein the first ligand is selected from an exciton delocalized ligand.

6. The quantum dot film according to claim 5, wherein the exciton delocalized ligand is selected from one or more of phenyl dithiocarbamate and N-heterocyclic carbine, the phenyl dithiocarbamate is selected from N-Phenyldithiocarbamic acid trimethylsilyl ester, the N-heterocyclic carbine is selected from 1,3-bis(2,4,6-trimethylphenyl) imidazole-2-ylidene.

7. The quantum dot film according to claim 1, wherein a mass percentage of the first ligand in the quantum dot film ranges from 2% to 15%.

8. The quantum dot film according to claim 7, wherein the mass percentage of the first ligand in the quantum dot film ranges from 2% to 8%.

9. The quantum dot film according to claim 1, wherein a mass ratio of the first quantum dot to the second quantum dot ranges from 1:1 to 1:10.

10. The quantum dot film according to claim 1, wherein a luminescence wavelength of the first quantum dot and a luminescence wavelength of the second quantum dot are in a same wavelength band, and an energy band width of the first quantum dot and an energy band width of the second quantum dot are the same, wherein, the energy band width refers to an energy range between a lowest energy level and a highest energy level in an energy band.

11. The quantum dot film according to claim 1, wherein the first quantum dot and the second quantum dot are independently selected from a core-shell structure quantum dot.

12. The quantum dot film according to claim 1, wherein the first quantum dot and the second quantum dot are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAlNAs, GaAINSb, GaAlPAs, GaAlPSb, GaInNP, GaInNAs, GaInNSb, GalnPAs, GaInPSb, InAINP, InAINAs, InAINSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and a material of the first quantum dot and a material of the second quantum dot are different.

13. A quantum dot light-emitting diode, comprising:
a first electrode;
a second electrode; and
a quantum dot light-emitting layer disposed between the first electrode and the second electrode;
wherein the quantum dot light-emitting layer is prepared by the quantum dot film of claim 1.

14. The quantum dot light-emitting diode according to claim 13, wherein one of the first electrode and the second electrode is an anode, and another is a cathode;
the quantum dot light-emitting diode comprises a hole injection layer, a hole transport layer, and an electron transport layer; wherein the hole injection layer and the hole transport layer are disposed between the anode and the quantum dot light-emitting layer, the hole injection layer is disposed close to the anode side, and the hole transport layer is disposed close to the quantum dot light-emitting layer, the electron transport layer is disposed between the cathode and the quantum dot light-emitting layer;
a material of the hole injection layer comprises any one of poly (ethylene dioxythiophene):polystyrene sulfonate, poly (9,9-dioctyl-fluorene-co-N-(4-butylphenyl)-diphenylamine), polyarylamine, poly(N-vinylcarbazole), polyaniline, polypyrrole, N,N′,N′-tetrakis (4-methoxyphenyl)-benzidine, 4-bis [N-(1-naphthyl)-N-phenyl-amino]biphenyl, 4,4′,4″-tri[phenyl(m-tolyphenyl) amino] triphenylamine, 4,4′,4″-tri (N-carbazolyl) triphenylamine, 4,4′-cyclohexylbis [N,N-bis(4-methylphenyl)] aniline, 4,4′4″-Tris(N,N-diphenylamino)triphenylamine doped with tetrafluoro-tetracyanoquinone dimethane, p-doped phthalocyanines, F4-TCNQ-doped N,N-diphenyl-N,N-bis (1-naphthyl)-1,1-biphenyl-4,4″-diamine, and hexaaza-benzphenanthrene-hexanthrene;
a material of the hole transport layer comprises one or more of an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, Poly (ethylene dioxythiophene):polystyrene sulfonate and derivatives thereof, poly(N-vinyl carbazole) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine, and spiro-NPB;
a material of the electron transport layer comprises a first inorganic material or an a first organic material, the first inorganic material comprises one or more of an undoped metal/non-metal oxide, a doped metal/non-metal oxide, an undoped semiconductor particle, a doped semiconductor particle, and a nitride; wherein the doped metal/non-metal oxide is doped with Al, Mg, In, Li, Ga, Cd, Cs or Cu, the doped semiconductor particle is doped with Al, Mg, In, Li, Ga, Cd, Cs or Cu; the first organic material comprises one or more of an oxazole compound, an isoxazole compound, a triazole compound, an isothiazole compound, an oxadiazole compound, a thiadiazole compound, a perylene compound, and an aluminum complex;
a material of the anode comprises one or more of ITO, IZO, ITZO, ICO, SnO₂, In₂O₃, Cd:ZnO, F:SnO₂, In:SnO₂, Ga:SnO₂, AZO, Ni, Pt, Au, Ag, Ir, and CNT;
a material of the cathode comprises one or more of Ca, Ba, Ca/Al, LiF/Ca, LiF/Al, BaF₂/Al, CsF/Al, CaCO₃/Al, BaF₂/Ca/Al, Al, Mg, Au:Mg, and Ag:Mg.

15. A preparation method for a quantum dot light-emitting diode, comprising:
providing a first electrode;
forming a quantum dot film on the first electrode, and thermally annealing to form a quantum dot light-emitting layer; and
forming a second electrode on the quantum dot light-emitting layer;
wherein, the quantum dot film comprises quantum dots, surfaces of at least part of the quantum dots are connected with a first ligand, the quantum dots comprise a first quantum dot and a second quantum dot, wherein, the first ligand is configured to stack first excitons generated by the first quantum dot with second excitons generated by the second quantum dot.

16. The method according to claim 15, wherein forming a quantum dot film on the first electrode comprises: disposing a quantum dot ink on the first electrode to form a wet film, placement treating, and drying to form the quantum dot film.

17. The method according to claim 16, wherein a pressure of the placement treating is a normal pressure, and a time of the placement treating is from 2 min to 10 min.

18. The method according to claim 17, wherein a temperature of the placement treating is from 10° C. to 35° C.

19. The method according to claim 15, wherein a temperature of the thermally annealing is between 50° C. and 120° C., and a time of the thermally annealing is between 5 min and 30 min.

20. The method according to claim 15, wherein one of the first electrode and the second electrode is an anode, and another is a cathode;
the method comprises: forming a hole injection layer and a hole transport layer between the anode and the quantum dot light-emitting layer, wherein, the hole injection layer is disposed close to the anode side, and the hole transport layer is disposed close to the quantum dot light-emitting layer; and forming an electron transport layer between the cathode and the quantum dot light-emitting layer;
wherein a material of the hole injection layer comprises any one of poly (ethylene dioxythiophene):polystyrene sulfonate, poly (9,9-dioctyl-fluorene-co-N-(4-butylphenyl)-diphenylamine), polyarylamine, poly(N-vinylcarbazole), polyaniline, polypyrrole, N,N′,N′-tetrakis (4-methoxyphenyl)-benzidine, 4-bis [N-(1-naphthyl)-N-phenyl-amino]biphenyl, 4,4′,4″-tri[phenyl(m-tolyphenyl) amino] triphenylamine, 4,4′,4″-tri (N-carbazolyl) triphenylamine, 4,4′-cyclohexylbis [N,N-bis(4-methylphenyl)] aniline, 4,4′4″-Tris(N,N-diphenylamino)triphenylamine doped with tetrafluoro-tetracyanoquinone dimethane, p-doped phthalocyanines, F4-TCNQ-doped N,N-diphenyl-N,N-bis (1-naphthyl)-1,1-biphenyl-4,4″-diamine, and hexaaza-benzphenanthrene-hexanthrene;
a material of the hole transport layer comprises one or more of an aryl amine, polyaniline, polypyrrole, poly(p)phenylene vinylene and derivatives thereof, copper phthalocyanine, aromatic tertiary amines, polynuclear aromatic tertiary amines, 4,4′-bis (p-carbazolyl)-1,1′-biphenyl compound, N,N,N′,N′-tetraarylbenzidine, Poly (ethylene dioxythiophene):polystyrene sulfonate and derivatives thereof, poly(N-vinyl carbazole) and derivatives thereof, poly(methacrylate) and derivatives thereof, poly(9,9-octylfluorene) and derivatives thereof, poly(spirofluorene) and derivatives thereof, N,N′-di (naphthalene-1-yl)-N,N′-diphenylbenzidine, and spiro-NPB;
a material of the electron transport layer comprises a first inorganic material or an a first organic material, the first inorganic material comprises one or more of an undoped metal/non-metal oxide, a doped metal/non-metal oxide, an undoped semiconductor particle, a doped semiconductor particle, and a nitride; wherein the doped metal/non-metal oxide is doped with Al, Mg, In, Li, Ga, Cd, Cs or Cu, the doped semiconductor particle is doped with Al, Mg, In, Li, Ga, Cd, Cs or Cu; the first organic material comprises one or more of an oxazole compound, an isoxazole compound, a triazole compound, an isothiazole compound, an oxadiazole compound, a thiadiazole compound, a perylene compound, and an aluminum complex;
a material of the anode comprises one or more of ITO, IZO, ITZO, ICO, SnO₂, In₂O₃, Cd:ZnO, F:SnO₂, In:SnO₂, Ga:SnO₂, AZO, Ni, Pt, Au, Ag, Ir, and CNT;
a material of the cathode comprises one or more of Ca, Ba, Ca/Al, LiF/Ca, LiF/Al, BaF₂/Al, CsF/AI, CaCO₃/Al, BaF₂/Ca/Al, Al, Mg, Au:Mg, and Ag:Mg.
